(19) United States
(12) Patent Application Publication
(10) Pub. No.: US 2009/0215273 A1
(43) Pub. Date: Aug. 27, 2009

(54) METHOD OF FABRICATING A SEMICONDUCTOR DEVICE

(75) Inventor: Choong Bae KIM, Yongin-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 12/163,602

(22) Filed: Jun. 27, 2008

(30) Foreign Application Priority Data
Feb. 27, 2008 (KR) 2008-17693

(51) Int. Cl. H01L 21/461

(52) U.S. Cl. 438/710

(57) ABSTRACT

In a method of fabricating a semiconductor device, a charge storage layer is etched using an etching gas by which a tunnel insulating layer is less etched than the charge storage layer. Thus, it is possible to prevent the tunnel insulating layer formed below the charge storage layer from being damaged when the charge storage layer is patterned. The method of fabricating a semiconductor device includes providing a semiconductor substrate on which a tunnel insulating layer and a charge storage layer formed of an insulating material are formed; forming a stack layer on the charge storage; patterning the stack layer to expose a portion of the charge storage layer; and etching the exposed charge storage layer using as etching gas hydrogen bromide (HBr) gas, chloride (Cl₂) gas, hydrogen chloride (HCl) gas or a mixture gas thereof.

### CROSS-REFERENCE TO RELATED APPLICATIONS

This application claims priority from Korean Patent Application No. 10-2008-0017693, filed on Feb. 27, 2008, the contents of which are incorporated herein by reference in its entirety.

### BACKGROUND OF THE INVENTION

The present invention relates to a method of fabricating a semiconductor device, and more particularly to a method of fabricating a semiconductor device which can minimize damage to an oxide layer when a nitride layer formed on the oxide layer is etched.

In semiconductor devices, a non-volatile memory device may include a charge storage layer formed of an insulating layer (for example, a nitride layer) instead of a polysilicon layer which is a conductive layer.

The non-volatile memory device in which the charge storage layer is formed of a conductive layer has a disadvantage in that if there is a fine defect on a floating gate, a retention time of charges becomes significantly lowered. However, in the non-volatile memory device in which an insulating layer such as a nitride layer is formed as the charge storage layer, there is an advantage in that process defects are reduced due to a property of the nitride layer.

In addition, in the non-volatile memory device in which the charge storage layer is formed of a conductive layer, since a tunnel insulating layer having a thickness of approximately 70 Å or more is formed below a floating gate, there is a limit in realizing a low voltage operation and a high speed operation of the semiconductor device. In the non-volatile memory device in which an insulating layer acts as the lo charge storage layer, however, it is possible to decrease a thickness of a direct tunneling insulating layer formed below the charge storage layer. Thus, the memory device may operate at a low voltage and low power with a high speed.

In general, when the non-volatile memory device includes an insulating layer that is utilized as the charge storage layer, an isolation layer is formed on a semiconductor substrate by a shallow trench isolation (STI) process. An oxide layer as the direct tunneling insulating layer, a nitride layer as the charge storage layer for storing electric charge therein, an oxide layer as the charge blocking layer and a conductive layer as a gate electrode layer are then formed on the semiconductor substrate including the isolation layer. Subsequently, an etching process for forming a gate pattern is performed to form a gate constituting the memory cell.

As described above, however, since the direct tunneling insulating layer has an extremely small thickness, if the exposed direct tunneling insulating layer is etched together with the charge storage layer during an etching process for the charge storage layer, an active region of the semiconductor substrate is directly exposed so that the active region may be damaged. As a result, a operational characteristic of the non-volatile memory device may be adversely affected.

In the process for fabricating the semiconductor device, after forming a gate on a gate insulating layer, a gate spacer can be formed on a side wall of the gate to protect the gate. In general, an insulating layer, for example, a nitride layer having a thickness sufficient for maintaining a step of the gate, is formed on the semiconductor substrate including the gate. An anisotropic etching process for the nitride layer is then performed to form the gate spacer. However, during the etching process for the nitride layer, the exposed gate insulating layer can be etched together with the nitride layer. In this case, the active region of the semiconductor substrate is also directly exposed so that the active region may be damaged. Due to damage to the active region, an operational characteristic of the non-volatile memory device may be adversely affected.

### SUMMARY OF THE INVENTION

In the method of fabricating a semiconductor device according to the present invention, a process for etching a charge storage layer is performed using an etching gas by which a tunnel insulating layer is less etched than the charge storage layer. Thus, it is possible to prevent the tunnel insulating layer formed below the charge storage layer from being damaged when the charge storage layer is patterned.

The method of fabricating a semiconductor device according to one embodiment of the present invention comprises the steps of providing a semiconductor substrate on which a tunnel insulating layer and a charge storage layer formed of an insulating material are formed; forming a stack layer on the charge storage layer; patterning the stack layer to expose a portion of the charge storage layer; and etching the exposed charge storage layer using as an etching gas one of hydrogen bromide (HBr) gas, chloride (Cl₂) gas, hydrogen chloride (HCl) gas, or a mixture gas thereof.

The tunnel insulating layer may be formed of an oxide layer. The charge storage layer may be formed of a nitride layer. A first additive gas may be mixed with the etching gas for increasing an etching selection ratio with respect to the tunnel insulating layer. The step of etching the charge storage layer may further comprise the step of mixing the first additive gas with the etching gas before the tunnel insulating layer is exposed while the charge storage layer is etched by the etching gas. The step of etching the charge storage layer may be performed using the etching gas with which the first additive gas is mixed until the tunnel insulating layer is exposed. The first additive gas may comprise oxygen (O₂) gas. A second additive gas may be mixed with the etching gas for increasing an etching selection ratio with respect to the charge storage layer. The second additive gas may comprise one of argon (Ar) gas, helium (He) gas, xenon (Xe) gas, nitrogen (N₂) gas or a mixture gas thereof. The step for etching the charge storage layer may be performed in a state where a bias power of 20 to 200 W is applied.

A method of fabricating a semiconductor device according to another embodiment of the present invention comprises the steps of providing a semiconductor substrate on which an oxide layer and a nitride layer are formed; and etching the nitride layer using as an etching gas one of hydrogen bromide (HBr) gas, chloride (Cl₂) gas, hydrogen chloride (HCl) gas or a mixture gas thereof.

A first additive gas may be mixed with the etching gas for increasing an etching selection ratio with respect to the oxide layer. The step of etching the nitride layer further comprises the step of mixing the first additive gas with the etching gas before the oxide layer is exposed while the nitride layer is etched by the etching gas. The step of etching the nitride layer is performed using the etching gas with which the first additive gas is mixed until the oxide layer is exposed. The first additive gas may comprise oxygen (O₂) gas. A second additive gas may be mixed with the etching gas to increase an etching selection ratio with respect to the nitride layer. The second additive gas may comprise one of argon (Ar) gas, helium (He) gas, xenon (Xe) gas, nitrogen (N₂) gas or a mixture gas thereof.

### BRIEF DESCRIPTION OF THE DRAWINGS

The above and other features and advantages of the present invention will become readily apparent by reference to the following detailed description when considered in conjunction with the accompanying drawings wherein:

FIG. 1A to FIG. 1F are sectional views of a semiconductor device illustrating a method of fabricating a semiconductor device according to one embodiment of the present invention;

FIG. 2 is a photograph of a section of a semiconductor showing an etching process performed up to a charge blocking layer according to one embodiment of the present invention;

FIG. 3 is a photograph of a section of a semiconductor showing an etching process performed up to a charge storage layer according to one embodiment of the present invention; and

FIG. 4A and FIG. 4B are sectional views of a semiconductor device illustrating a method of fabricating a semiconductor device according to another embodiment of the present invention.

### DESCRIPTION OF SPECIFIC EMBODIMENTS

Hereinafter, the preferred embodiments of the present invention will be explained in more detail with reference to the accompanying drawings.

However, the present invention is not limited to the embodiment described below. It should be understood that numerous other modifications and embodiments can be devised by those skilled in the art that will fall within the spirit and scope of the principles of this disclosure. More particularly, variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art. In addition, in the detailed description, the expression of “a certain layer is formed on another layer or a semiconductor substrate” means that the certain layer can be formed directly on another layer or the semiconductor substrate and that a third layer can be disposed between the certain layer and another layer or the semiconductor substrate. A thickness or a dimension of a respective layer shown in the drawings may be illustrated out of scale for convenience and clarity of explanation.

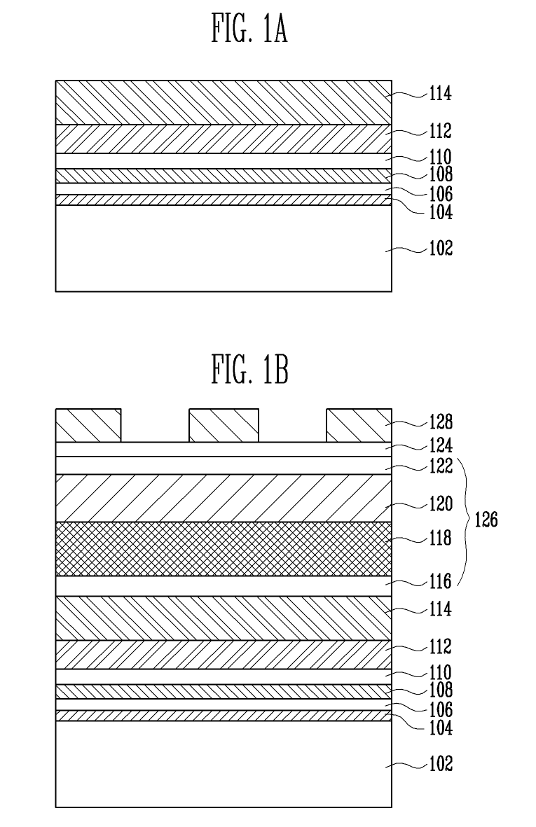

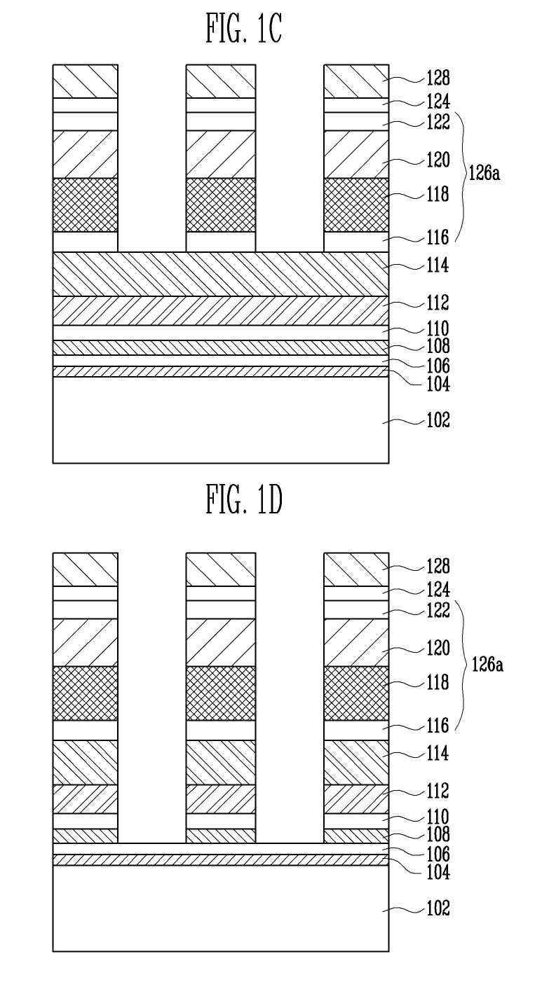

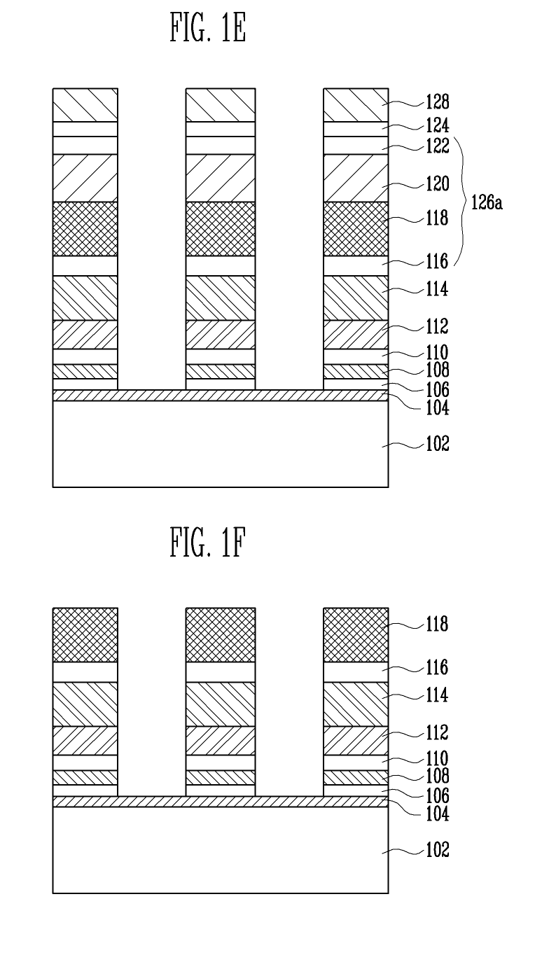

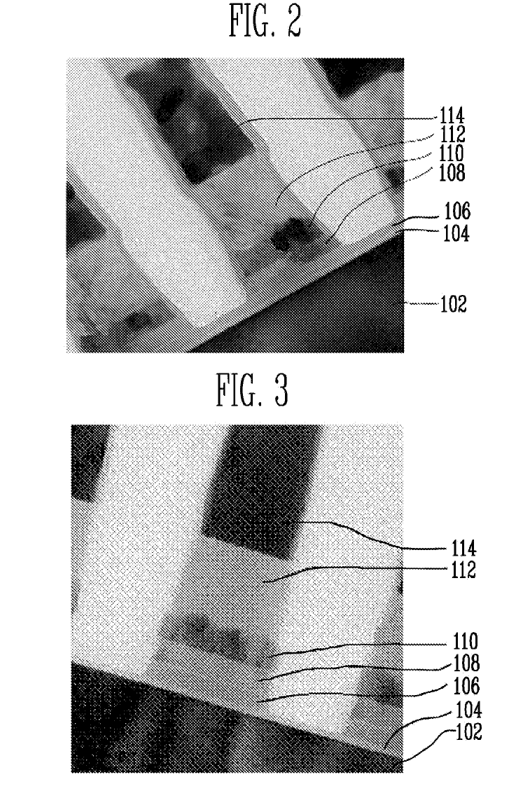

FIG. 1A to FIG. 1F are sectional views of a semiconductor device illustrating a method of fabricating a semiconductor device according to one embodiment of the present invention. FIG. 2 is a photograph of a section of a semiconductor showing an etching process performed up to a charge blocking layer according to one embodiment of the present invention. FIG. 3 is a photograph of a section of a semiconductor showing an etching process performed up to a charge storage layer according to one embodiment of the present invention.

Referring to FIG. 1A, a screen oxide layer (not shown) is formed on a semiconductor substrate 102. In order to fabricate a non-volatile memory device in the semiconductor device, a well ion implanting process is performed on the semiconductor substrate 102 to form a well region (not shown). The well region may have a triple structure. Subsequently, a threshold voltage ion implanting process is performed on the semiconductor substrate 102 to adjust a threshold voltage of the non-volatile memory device. The screen oxide layer (not shown) may prevent damage to a surface of the semiconductor substrate 102 when the well ion implanting process or the threshold voltage ion implanting process is carried out.

The screen oxide layer (not shown) is removed, and a trench (not shown) is then formed on an isolation region of the semiconductor substrate 102. The trench (not shown) is filled with insulative material to form an isolation layer (not shown). The isolation layer (not shown) defines an active region.

Subsequently, a tunnel insulating layer 104 is formed on the semiconductor substrate 102. Since electric charges can pass through the tunnel insulating layer 104 through a direct tunnel phenomenon, the electric charges below the tunnel insulating layer 104 may pass through the tunnel insulating layer 104 and may then be transported to a charge storage layer formed above the tunnel insulating layer 104 during a program operation. Furthermore, the electric charges stored in the charge storage layer may be transported to a location below the tunnel insulating layer 104 through the tunnel insulating layer 104 during an erase operation. The tunnel insulating layer 104 may be formed of an oxide layer with a thickness of approximately 40 Å.

A charge storage layer 106 is formed on the tunnel insulating layer 104. The charge storage layer 106 is formed on the overall semiconductor substrate 102 including a plurality of active regions. The charge storage layer 106 may be formed of insulative material, for example, nitride. If the charge storage layer 106 is formed of insulative material, it is possible to form the charge storage layer 106 having a thickness smaller than that of the charge storage layer formed of conductive material. Thus, a size of the non-volatile memory device may be reduced and a retention characteristic may be improved to improve performance of the non-volatile memory device.

A charge blocking layer 108 is formed on the charge storage layer 106. The charge blocking layer 108 can prevent the electric charges stored in the charge storage layer 106 from being discharged to a layer formed on the charge storage layer 106 by a reverse-tunneling effect. The charge blocking layer 108 can be formed of insulative material with a high dielectric ratio, for example, aluminum oxide (Al₂O₃), with a thickness of approximately 150 Å.

A plurality of gate electrode layers, for example, a first gate electrode layer 110, a second gate electrode layer 112 and a third gate electrode layer 114, are formed on the charge blocking layer 108. The first gate electrode layer 110 may be formed of conductive material, for example, titanium nitride (TiN), with a thickness of approximately 200 Å. The second gate electrode layer 112 may be formed of conductive material, for example, polysilicon, with a thickness of approximately 500 Å. The third gate electrode layer 114 may be formed of conductive material, for example, tungsten silicide (WSiₓ), with a thickness of approximately 1,100 Å.

Referring to FIG. 1B, a hard mask 126, in which a plurality of layers are laminated, is formed on the third gate electrode layer 114. The hard mask 126 is used in a subsequent process for etching a gate. To form the hard mask 126, a capping layer 116 is formed on the third gate electrode layer 114. The capping layer 116 may be formed of silicon oxynitride (SiON) with a thickness of approximately 200 Å. A first hard mask layer 118 and a second hard mask layer 120 are formed on the capping layer 116. The first hard mask layer 118 may be formed of oxide, for example, tetra ethyl ortho silicate (TEOS), with a thickness of approximately 1,400 Å. The second hard mask layer 120 may be formed of carbon, for example, amorphous carbon, with a thickness of approximately 2,000 Å. A protective layer 122 may be formed on the second hard mask layer 200. The protective layer 122 prevents the second hard mask layer 120 from being damaged in a subsequent process and may act as an anti-reflection layer. The protective layer 122 may be formed of silicon oxynitride (SiON), with a thickness of approximately 400 Å. As a result, the hard mask 126 comprising the capping layer 116, the first hard mask layer 118, the second hard mask layer 120 and the protective layer 122 is formed.

An anti-reflection layer 124 is formed on the protective layer 122. A diffused reflection can be prevented in a subsequent exposure process by the anti-reflection layer 124 to increase resolution in the exposure process. The anti-reflection layer may be formed with a thickness of approximately 240 Å. Subsequently, a photoresist layer is formed on the anti-reflection layer 214. An exposure process and a developing process are performed on the photoresist layer to form a photoresist pattern 128.

Referring to FIG. 1C, the anti-reflection layer 124, the protective layer 122, the second hard mask layer 120, the first hard mask layer 118 and the capping layer 116 are etched and patterned through an etching process in which the photoresist pattern 128 is utilized as an etching mask. Thus, a hard mask pattern 126a is formed. In order to form the hard mask pattern 126a, the etching process is performed under etching conditions which are suitable for the etching-target layers constituting the hard mask pattern 126a. During the etching process for forming the hard mask pattern 126a, a cleaning process may be additionally performed to remove impurities generated in the etching process.

Referring to FIG. 1D and FIG. 2, the third gate electrode layer 114, the second gate electrode layer 112, the first gate electrode layer 110 and the charge blocking layer 108 are etched and patterned through an etching process in which the hard mask pattern 126a is used as an etching mask. As a result, the charge storage layer 106 formed below the charge blocking layer 108 is exposed. The etching process is performed under etching conditions which are suitable for the respective etching-target layers.

Referring to FIG. 1E and FIG. 3, an etching process for the exposed charge storage layer 106 is performed. The etching process is performed under a condition by which the tunnel insulating layer 104 is less etched than the charge storage layer 106 (e.g., the oxide layer is less etched than the nitride layer) to prevent the tunnel insulating layer 104 formed below the charge storage layer 106 from being damaged.

To achieve the above result, the etching process for the charge storage layer 106 is performed using as an etching gas one of hydrogen bromide (HBr) gas, chloride (Cl₂) gas, hydrogen chloride (HCl) gas, or a mixture gas thereof. The above etching gas has a high etching selection ratio with respect to the oxide layer and has a property by which an amount of the oxide layer to be etched is less than that of the nitride layer to be etched. Accordingly, if the charge storage layer 106 formed of the nitride layer is etched using the above etching gas, an etched amount of the tunnel insulating layer 104 exposed by etching of the charge storage layer 106 is reduced to prevent the tunnel insulating layer 104 from being damaged.

In addition, in order to increase an etching selection ratio with respect to the tunnel insulating layer formed of the oxide layer to decrease the amount of the tunnel insulating layer 140 to be etched, a first additive gas, for example, oxygen (O₂) gas, may be mixed with the above etching gas. A time at which to mix oxygen (O₂) gas with the etching gas may be varied according to a process time required in an etching process for removing the charge storage layer 106. In other words, if a process time for etching the charge storage layer 106 is sufficient, oxygen (O₂) gas may be added to the above etching gas before etching the charge storage layer 106, and the etching process for the charge storage layer 106 is then performed. However, in order to reduce the amount of time required for etching the charge storage layer 106, an etching process of the charge storage layer 106 is performed first using the above etching gas, and oxygen (O₂) gas may then be added to the above etching gas before the charge storage layer 106 is completely etched. In this case, while the charge storage layer 106 is etched more rapidly, damage to the tunnel insulating layer 104 may be prevented.

In addition, in order to increase an etching selection ratio with respect to the charge storage layer, which is the nitride layer, and to form vertically the gate profile during the above etching process, a second additive gas, for example, one of argon (Ar) gas, helium (He) gas, xenon (Xe) gas, nitrogen (N₂) gas, or a mixture gas of thereof, can be mixed with the etching gas.

In the above process for etching the charge storage layer 106, a relatively low bias power, for example, a bias power of 20 to 200 W, is applied to prevent damage to the tunnel insulating layer 104. In addition, during the etching process, upper portions of the photoresist pattern 128 and the hard mask 126 may be partially removed.

As described above, the gate of the semiconductor device according to the present invention prevents the tunnel insulating layer 104 from being damaged, and the charge storage layer 106 can be formed separately on each active region. Compared with forming the charge storage layer on an overall semiconductor substrate, the present invention can solve the problem that charges stored in the charge storage layer 106 are transported to the adjacent memory cell to lower a retention characteristic.

To prevent a side surface of the gate, which is etched during a gate etching process, from being damaged, a nitride layer acting as a protective layer (not shown) is formed on the side surface of the gate. The protective layer (not shown) and the exposed charge storage layer 106 may then be etched together.

Referring to FIG. 1F, the remaining photoresist pattern 128 (see FIG. 1E), anti-reflection layer 124 (see FIG. 1E), protective layer 122 (see FIG. 1E) and second hard mask layer 120 (see FIG. 1E) are removed to complete a formation of the gate of the non-volatile memory device.

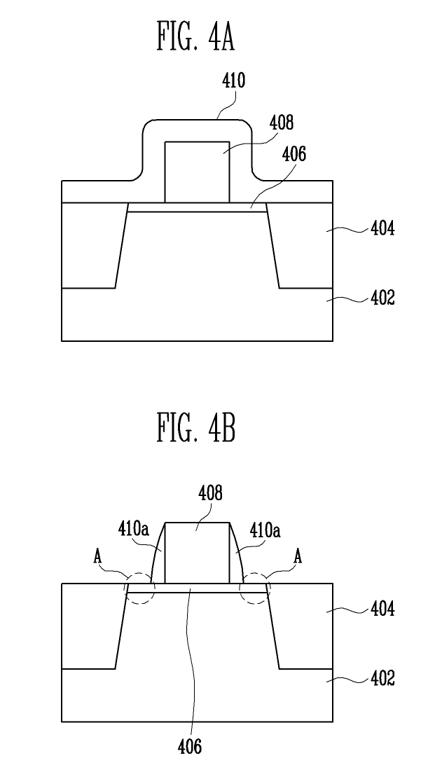

FIG. 4A and FIG. 4B are sectional views of a semiconductor device for illustrating a method of a fabricating a semiconductor device according to another embodiment of the present invention.

FIG. 4A, an isolation layer 404 is formed on an isolation region of a semiconductor substrate 402 to define an active region of the semiconductor substrate 402. A gate insulating layer 406 is formed on the active region of the semiconductor substrate 402. The gate insulating layer 406 may be formed of an insulating layer, for example, an oxide layer. In addition, a gate 408 is formed on the gate insulating layer 406. Material used for forming a spacer is applied on the semiconductor substrate 402 including the gate 408 to form a spacer-material layer 410 on an upper face and side walls of the gate 408.

It is desirable that the spacer-material layer 410 is formed with a thickness sufficient for maintaining a step caused by the gate 408. The spacer-material layer 410 may be formed of an insulating layer, for example, a nitride layer.

Referring to FIG. 4B, a process for etching the spacer-material layer 410 is performed to allow the spacer-material layer 410 to remain on side surfaces of the gate 408. Preferably, an anisotropic etching process is performed as the etching process for the spacer-material layer 410.

While the spacer-material layer 410 formed on the gate insulating layer 406 is removed, the gate insulating layer 406 on a region A may be exposed during the etching process. Accordingly, it is preferable that the etching process for forming a spacer 410a is performed under the condition by which the gate insulating layer 406 is less etched than the spacer-material layer 410, for example, the oxide layer is less etched than the nitride layer, to prevent the gate insulating layer 406 formed on the region A from being damaged by the etching gas.

To achieve the above result, it is preferable that the etching process for the spacer-material layer 410 is performed using as an etching gas one of hydrogen bromide (HBr) gas, chloride (Cl₂) gas, hydrogen chloride (HCl) gas or a mixture gas thereof. The above etching gas has a high etching selection ratio with respect to the oxide layer and has a property by which an amount of the oxide layer to be etched is less than that of the nitride layer to be etched. Accordingly, if the spacer-material layer 410 formed of the nitride layer is etched using the above etching gas, an etched amount of the gate insulating layer 406 exposed by etching the spacer-material layer 410 is reduced to prevent the gate insulating layer 406 from being damaged.

In addition, in order to increase an etching selection ratio with respect to the oxide layer, a first additive gas, for example, oxygen (O₂) gas, may be mixed with the above etching gas. A time at which the oxygen (O₂) gas is mixed with the etching gas can be varied according to a etching process time required for removing the spacer-material layer 410. In other words, if a process time for etching the spacer-material layer 410 is sufficient, oxygen (O₂) gas may be added to the above etching gas early in the etching process for the spacer-material layer 410, and the etching process for the charge storage layer 106 is then performed. However, in order to reduce the time required to etch the spacer-material layer 410, an etching process for the spacer-material layer 410 is performed using the above etching gas, and oxygen (O₂) gas is then added to the above etching gas before the spacer-material layer 410 is completely etched. While the spacer-material layer 410 is etched more rapidly, damage to the gate insulating layer 406 may be prevented.

In addition, in order to increase an etching selection ratio with respect to the nitride layer during the above etching process, a second additive gas, for example, one of argon (Ar) gas, helium (He) gas, xenon (Xe) gas, nitrogen (N₂) gas or a mixture gas of thereof, may be mixed with the etching gas,

In the above process for etching the spacer-material layer 410, a relatively low bias power, for example, a bias power of 20 to 200 W is applied, so that damage to the gate insulating layer 406 may be prevented.

According to the method of fabricating the semiconductor device as described above, it is possible to prevent the exposed gate insulating layer 406 from being damaged during the etching process for forming the gate spacer 410a.

According to the method of fabricating a semiconductor device, since the process for etching the charge storage layer is performed using the etching gas by which the tunnel insulating layer is less etched than the charge storage layer, it is possible to prevent the tunnel insulating layer formed below the charge storage layer from being damaged when the charge storage layer is patterned. Accordingly, the charge storage layer is easily patterned to form separately the charge storage layer on each active region. Thus, the present invention can solve the problems such as a potential drop caused by a transportation of charges stored in the charge storage layer to the adjacent memory cell, a variation of the threshold voltage, a lowering of data retention characteristic etc.

Furthermore, the method of fabricating a semiconductor device in accordance with the present invention prevents damage to the gate insulating layer during the etching process for forming the spacer formed of a nitride layer on the gate insulating layer formed of an oxide layer.

Although the method of fabricating the semiconductor device is illustrated herein as one embodiment, the present invention is not limited thereto. In other words, it will be apparent that the present invention can be applied to other semiconductor fabricating processes which can prevent damage to an oxide layer that is exposed when the nitride layer of the semiconductor substrate on which the oxide layer and the nitride layer are formed is etched.

The embodiments disclosed herein have been proposed to allow a person skilled in the art to easily implement the present invention, and the person skilled in the part may implement the present invention by a combination of these embodiments. Therefore, the scope of the present invention is not limited by or to the embodiments as described above, and should be construed to be defined only by the appended claims and their equivalents.

What is claimed is:

1. A method of fabricating a semiconductor device, the method comprising:
providing a semiconductor substrate on which a tunnel insulating layer and a charge storage layer formed of insulating material are formed;
forming a stack layer over the charge storage layer;
patterning the stack layer to expose a portion of the charge storage layer; and
etching the exposed charge storage layer using as an etching gas one of hydrogen bromide (HBr) gas, chloride (Cl₂) gas, hydrogen chloride (HCl) gas and a mixture gas thereof.

2. The method of claim 1, wherein the tunnel insulating layer is formed of an oxide layer.

3. The method of claim 1, wherein the charge storage layer is formed of a nitride layer.

4. The method of claim 1, wherein the etching gas comprises a first additive gas for increasing an etching selection ratio with respect to the tunnel insulating layer.

5. The method of claim 4, wherein etching the charge storage layer further comprises mixing the first additive gas with the etching gas before the tunnel insulating layer is exposed while the charge storage layer is etched by the etching gas.

6. The method of claim 4, wherein etching the charge storage layer is performed using the etching gas with which the first additive gas is mixed until the tunnel insulating layer is exposed

7. The method of claim 4, wherein the first additive gas comprises oxygen (O₂) gas.

8. The method of claim 1, wherein the etching gas comprises a second additive gas for increasing an etching selection ratio with respect to the charge storage layer.

9. The method of claim 8, wherein the second additive gas comprises one of argon (Ar) gas, helium (He) gas, xenon (Xe) gas, nitrogen (N₂) gas and a mixture gas thereof.

10. The method of claim 8, wherein etching the charge storage layer is performed in a state where a bias power of 20 to 200 W is applied.

11. The method of claim 1, wherein the stack layer comprises a charge blocking layer, a gate electrode layer and a hard mask.

12. A method of fabricating a semiconductor device, the method comprising:
providing a semiconductor substrate on which an oxide layer and a nitride layer are formed; and
etching the nitride layer using as an etching gas one of hydrogen bromide (HBr) gas, chloride (Cl₂) gas, hydrogen chloride (HCl) gas and a mixture gas thereof.

13. The method of claim 12, wherein the etching gas comprises a first additive gas for increasing an etching selection ratio with respect to the oxide layer.

14. The method of claim 13 wherein etching the nitride layer further comprises mixing the first additive gas with the etching gas before the oxide layer is exposed while the nitride layer is etched by the etching gas.

15. The method of claim 13 wherein etching the nitride layer is performed using the etching gas with which the first additive gas is mixed until the oxide layer is exposed.

16. The method of claim 13 wherein the first additive gas comprises oxygen (O₂) gas.

17. The method of claim 12 wherein the etching gas comprises a second additive gas for increasing an etching selection ratio with respect to the nitride layer.

18. The method of claim 17 wherein the second additive gas comprises one of argon (Ar) gas, helium (He) gas, xenon (Xe) gas, nitrogen (N₂) gas and a mixture gas thereof.

19. A method of fabricating a semiconductor device, the method comprising:
forming an isolation layer and a gate insulating layer over a semiconductor substrate;
forming a gate over the gate insulating layer;
forming a spacer-material layer over the gate, the gate insulating layer and the isolation layer; and
etching the spacer-material layer such that the spacer-material layer remains on side surfaces of the gate, wherein the spacer-material layer is etched using as an etching gas one of: hydrogen bromide (HBr) gas, chloride (Cl₂) gas, hydrogen chloride (HCl) gas and a mixture gas thereof.

20. The method of claim 19, wherein the spacer material layer comprises a nitride layer and the insulating layer comprises an oxide layer.

21. The method of claim 19, wherein the etching gas comprises oxygen (O₂) gas for increasing an etching selection ratio with respect to the insulating layer.

22. The method of claim 19, wherein the etching gas comprises an additive gas for increasing an etching selection ratio with respect to the spacer-material layer, the additive gas comprising one of argon (Ar) gas, helium (He) gas, xenon (Xe) gas, nitrogen (N₂) gas and a mixture gas thereof.
